(19) United States
(12) Patent Application Publication
(10) Pub. No.: US 2025/0210451 A1
(43) Pub. Date: Jun. 26, 2025

(54) PACKAGE STRUCTURE WITH MOLDING LAYER AND METHOD FOR MANUFACTURING THE SAME

(71) Applicant: Taiwan Semiconductor Manufacturing Co., Ltd., Hsinchu (TW)

(72) Inventors: Yi-Hsuan Wu, Miaoli County (TW); Tsung-Yu Chen, Hsinchu (TW); Chihting Lai, Hsinchu (TW); Lipu Kris Chuang, Hsinchu (TW); Hsin Ting Lin, Hsinchu County (TW)

(21) Appl. No.: 18/619,459

(22) Filed: Mar. 28, 2024

Related U.S. Application Data
(60) Provisional application No. 63/613,166, filed on Dec. 21, 2023.

(51) Int. Cl. H01L 23/42; H01L 21/56; H01L 23/00; H01L 23/29; H01L 23/31; H01L 23/538; H01L 25/00; H01L 25/065

(52) U.S. Cl. CPC H01L 23/42; H01L 21/56; H01L 23/295; H01L 23/3185; H01L 23/5383; H01L 24/16; H01L 24/32; H01L 24/73; H01L 24/92; H01L 25/0652; H01L 25/50; H01L 2224/16227; H01L 2224/32225; H01L 2224/73204; H01L 2224/92125

(57) ABSTRACT

A package structure and method for manufacturing the same are provided. A package structure is provided. The package structure includes a redistribution structure and a first package component and a second package component attached to the redistribution structure in a first direction and spaced apart from each other in a second direction. The package structure further includes an underfill formed around lower portions of the first package component and the second package component over the redistribution structure and a molding layer formed over the underfill and around upper portions of the first package component and the second package component. In addition, the molding layer includes a base material and fillers embedded in the base material. Furthermore, a thermal conductivity of the fillers is greater than about 400 W/mK.

### PRIORITY CLAIM AND CROSS-REFERENCE

This application claims priority to U.S. Provisional Application No. 63/613,166, filed on Dec. 21, 2023, the entirety of which is incorporated by reference herein.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (e.g., the number of interconnected devices per chip area) has generally increased while feature sizes (e.g., the smallest component that can be created using a fabrication process) have decreased. This scaling-down process generally provides benefits by increasing production efficiency and lowering associated costs.

A chip package not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A and 1B illustrate diagrammatic top views of a package structure in accordance with some embodiments.

FIGS. 2A to 2M illustrate cross-sectional views of intermediate stages of manufacturing the package structure in accordance with some embodiments.

FIG. 2G-1 illustrates an enlarged cross-sectional view of the package structure of a region R_2G shown in FIG. 2G in accordance with some embodiments.

FIG. 2I-1 illustrates an enlarged cross-sectional view of the package structure of a region R_2I shown in FIG. 2I in accordance with some embodiments.

FIGS. 3A and 3B illustrate cross-sectional views of intermediate stages of manufacturing a package structure 100′ in accordance with some embodiments.

FIG. 4 illustrates a diagrammatic top view of a package structure in accordance with some embodiments.

FIG. 5A illustrates a diagrammatic top view of a package structure in accordance with some embodiments.

FIG. 5B illustrates a cross-sectional view of the package structure shown along line X_{5A}-X_{5A}′ in FIG. 5A in accordance with some embodiments.

FIG. 5C illustrates a cross-sectional view of a package structure in accordance with some embodiments.

FIG. 6 illustrates a diagrammatic top view of a package structure in accordance with some embodiments.

FIGS. 7A and 7B illustrate diagrammatic top views of a package structure in accordance with some embodiments.

FIGS. 8A and 8B illustrate cross-sectional views of intermediate stages of manufacturing the package structure in accordance with some embodiments.

FIG. 9 illustrates a cross-sectional view of a package structure in accordance with some embodiments.

FIG. 10 illustrates a layout of a package structure in accordance with some embodiments.

FIG. 11A illustrates a diagrammatic top view of a package structure in accordance with some embodiments.

FIG. 11B illustrates a cross-sectional view of the package structure shown along line X_{11B}-X_{11B}′ in FIG. 11A in accordance with some embodiments.

FIG. 11C illustrates a cross-sectional view of a package structure in accordance with some embodiments.

FIG. 12 illustrates a layout of a package structure in accordance with some embodiments.

FIG. 13 illustrates a diagrammatic top view of a package structure in accordance with some embodiments.

FIG. 14 illustrates a layout of a package structure in accordance with some embodiments.

FIG. 15 illustrates a diagrammatic top view of a package structure in accordance with some embodiments.

FIG. 16 illustrates a layout of a package structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the disclosure may relate to package structures such as three-dimensional (3D) packaging, 3D-IC devices, and 2.5D packaging. Embodiments of the disclosure form a package structure including a substrate that carries one or more dies or packages and a protective element (such as a protective lid) aside the dies or packages. The protective element may also function as a warpage-control element and/or heat dissipation element.

Other features and processes may also be included. For example, testing structures may be included to aid in the verification testing of the 3D packaging, 3DIC devices, and/or 2.5 D packaging. The testing structures may include, for example, test pads formed in a redistribution layer or on a substrate that allows testing to be conducted using probes or probe cards and the like. Verification testing may be performed on intermediate structures as well as the final structure. Additionally, the structures and methods disclosed herein may be used in conjunction with testing methodologies that incorporate intermediate verification of known good dies to increase the yield and decrease costs.

A package structure may include various package components, and these package components may generate heat during the operation and may be seen as the hot spots in the devices. Accordingly, a molding layer with fillers having high thermal conductivity may be used to encapsulate the package components, so that the heat generated from the package components may be spread (e.g. dissipated) through the molding layer. In addition, the package structure may further include semiconductor dies electrically connected to the package components. These semiconductor dies may also generate heat during the operation. Therefore, the molding layer with fillers having high thermal conductivity may also be used to encapsulate the semiconductor dies. Accordingly, the temperature of the semiconductor device during operation may be reduced.

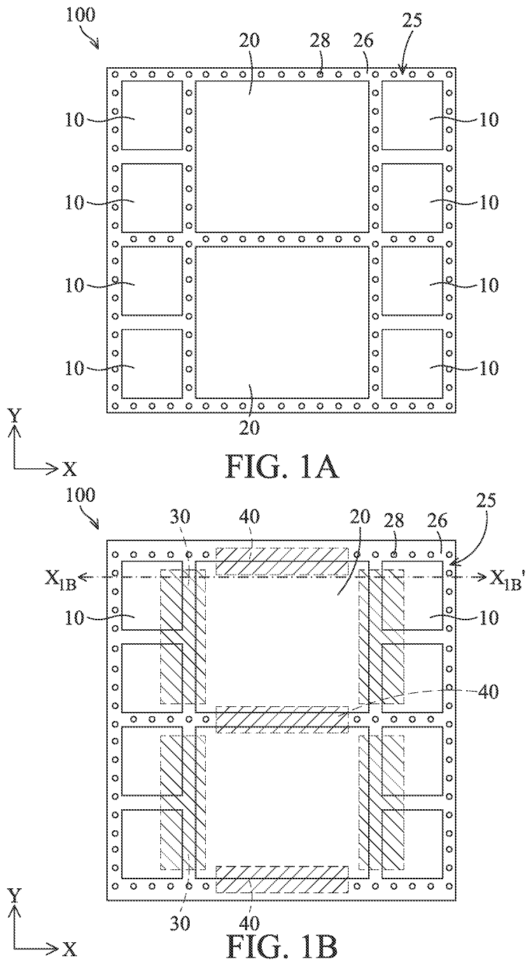

FIGS. 1A and 1B illustrate diagrammatic top views of a package structure 100 in accordance with some embodiments. For a better understanding of the structure, the X-Y-Z coordinate reference is provided in the following figures. In addition, the following figures may have been simplified for the sake of clarity to better understand the inventive concepts of the present disclosure. Additional features may be included, and some of the features described below may be replaced, modified, or eliminated.

More specifically, FIG. 1A illustrates the layout of package components 10 and 20 in the package structure 100 in accordance with some embodiments. In addition, the package components 10 and 20 are encapsulated (e.g. surrounded) by a molding layer 25 in accordance with some embodiments. In some embodiments, the spaces between the package components 10 and 20 in both X direction and Y direction are filled with the molding layer 25.

In some embodiments, the package components 10 and 20 are semiconductor dies with different functions. In some embodiments, the package components 10 include a memory device, such as a hybrid memory cube (HMC) module, a high bandwidth memory (HBM) module, or the like that includes multiple memory dies. In some embodiments, the package components 20 include system on chip (SoC) dies, chip scale packages (CSP), or a combination thereof. In some embodiments, the package components 10 are HBM dies and the package components 20 are SoC dies. The heat generated by the package components 10 may be seen as the hot spots in the package structure 100.

In some embodiments, one of the package component 20 is sandwiched between two of the package components 10 in X direction, as shown in the top view in FIG. 1A. In some embodiments, one of the package component 20 and two of the package components 10 are aligned with each other in the X direction. In some embodiments, the package components 10 are aligned with each other in the Y direction, and the package components 20 are aligned with each other in the Y direction. The package components 10 and 20 may be formed over a redistribution structure (not shown in FIG. 1A) and the detail of the processes will be described afterwards.

In some embodiments, the molding layer 25 includes a base material 26 and fillers 28 embedded in the base material 26. The fillers 28 may have high thermal conductivity, so that heat generated by the package components 10 and 20 may be spread laterally through the molding layer 25. In some embodiments, the thermal conductivity of the fillers 28 is greater than about 400 W/mK. In some embodiments, the concentration of the fillers 28 is in a range from about 20 wt % to about 80 wt %. The concentration of the fillers 28 should be high enough to provide sufficient thermal conductivity. On the other hand, the concentration of the fillers 28 may not be too high, or the fillers 28 may not be evenly mixed in the base material 26. In some embodiments, the particle size of the fillers 28 is in a range from about 10 μm to about 70 μm. In some embodiments, the fillers 28 are carbon-made particles, such as graphite, graphene, or diamond-like carbon particles. In some embodiments, the molding layer 25 includes more than one type of the fillers 28. In some embodiments, the molding layer 25 includes a single type of the fillers 28.

FIG. 1B further illustrates the layout of semiconductor dies 30 and 40 in the package structure 100 in accordance with some embodiments. More specifically, the semiconductor dies 30 and 40 are embedded active dies and are electrically coupled to the package components 10 and 20 through a redistribution structure in accordance with some embodiments. In some embodiments, the semiconductor dies 30 and 40 are embedded local interconnect dies.

In some embodiments, each of the semiconductor dies 30 is configured to provide electrical connection between one or more of the package components 10 and one or more of the package components 20 in X direction (electrical connection between two of the package components 10 and one of the package components 20 being shown in FIG. 1B). In some embodiments, each of the semiconductor dies 30 partially overlaps two of the package components 10 and one of the package components 20 in the top view, as shown in FIG. 1B. In some embodiments, each of the semiconductor dies 30 partially overlaps two adjacent sidewall surfaces of two package components 10 and one sidewall surface of one package component 20 in the top view. In some embodiments, each of the semiconductor dies 40 are configured to provide electric connection between two of the package components 30 in Y direction. In some embodiments, each of the semiconductor dies 40 vertically overlaps two of the package components 20 in the top view.

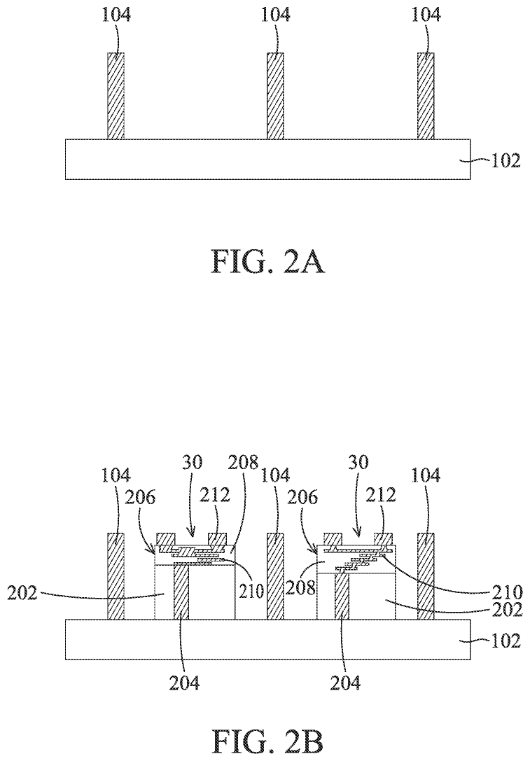

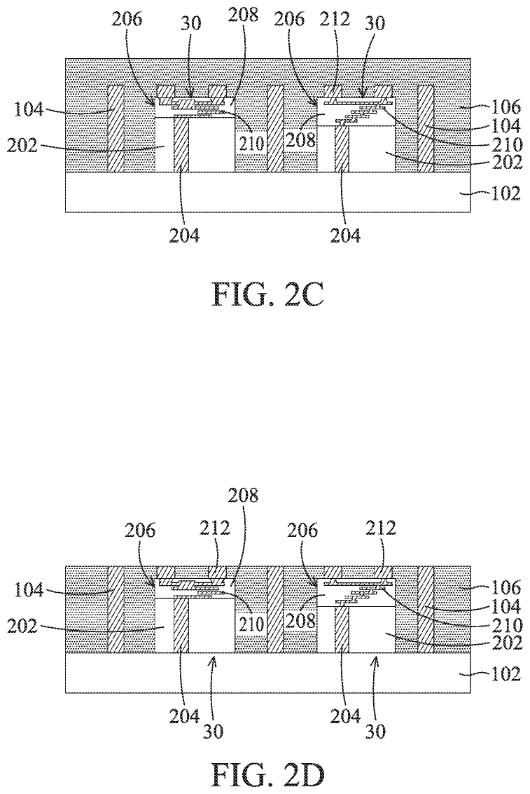

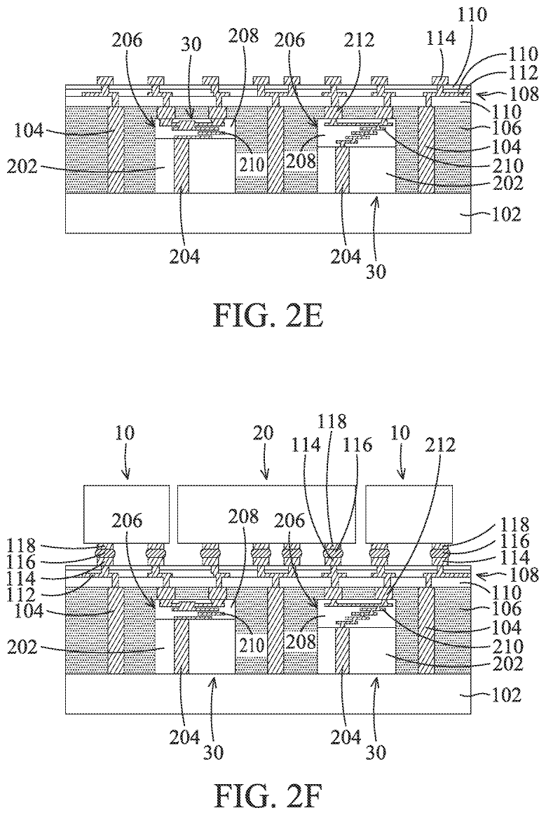

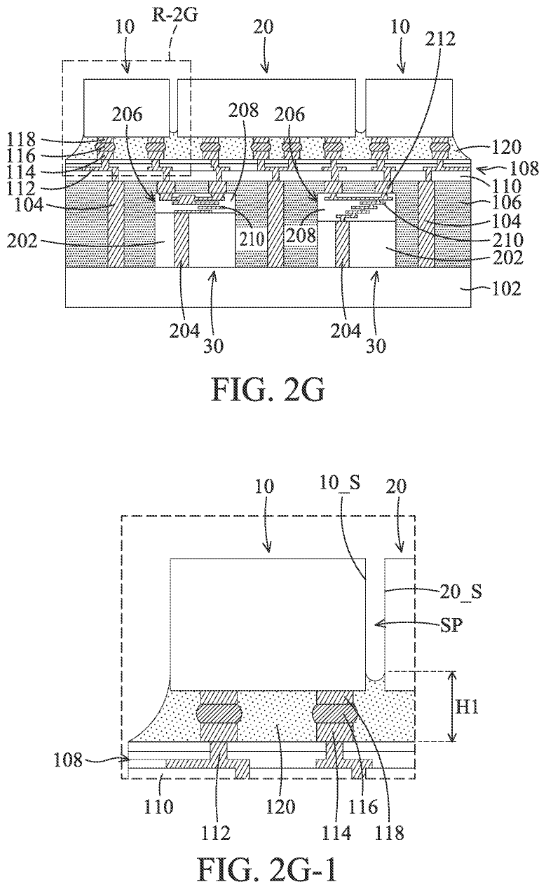

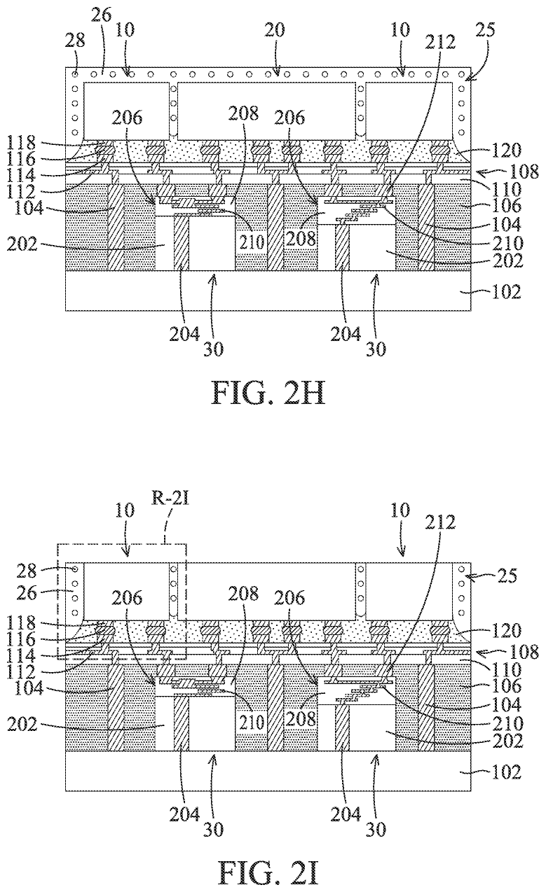

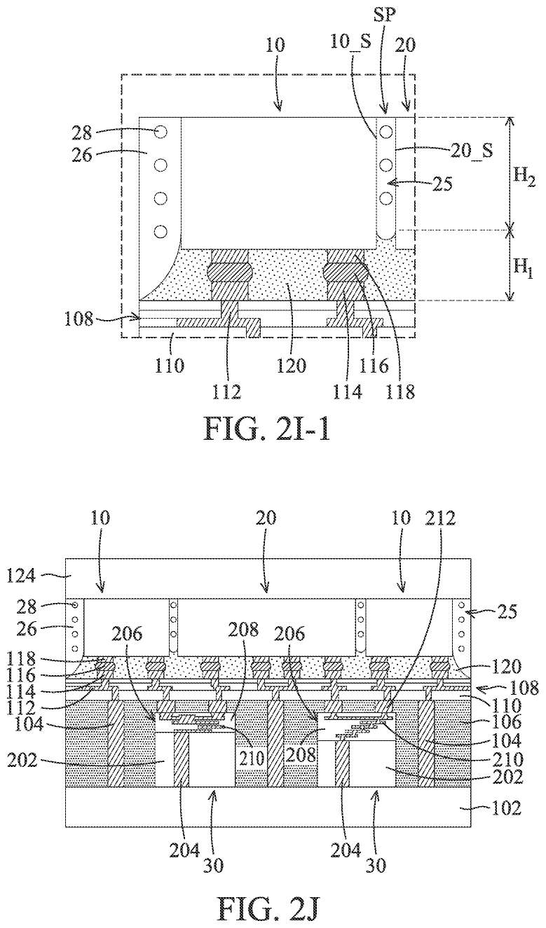

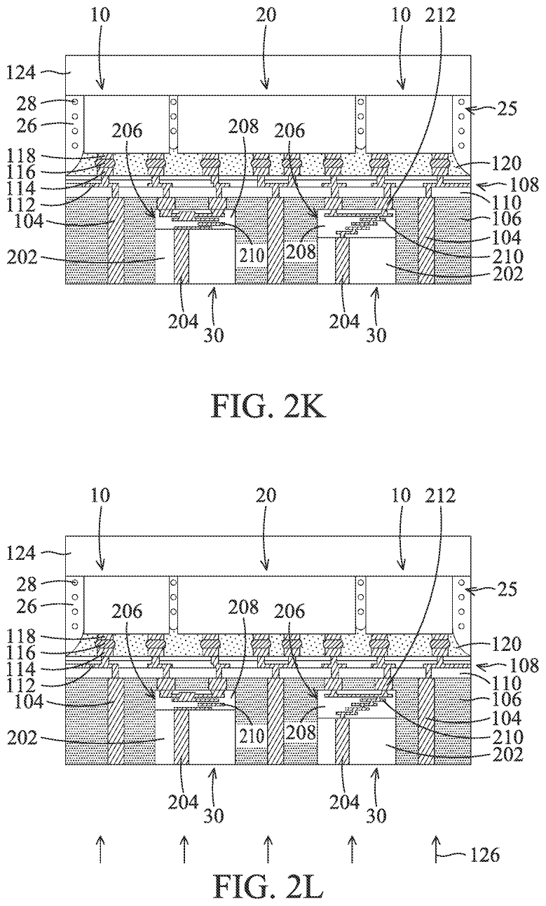

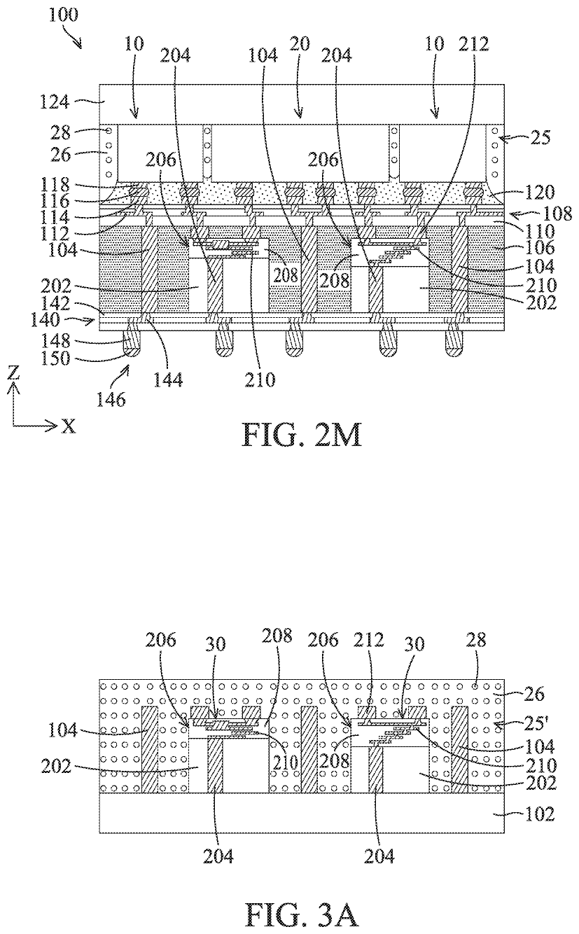

FIGS. 2A to 2M illustrate cross-sectional views of intermediate stages of manufacturing the package structure 100 in accordance with some embodiments. More specifically, the cross-sectional views are shown along line X_{1B}-X_{1B}′ in FIG. 1B in accordance with some embodiments.

As shown in FIG. 2A, through insulating vias (TIVs) 104 are formed over a carrier substrate 102 in accordance with some embodiments. The carrier substrate 102 may be configured to provide structural support during the manufacturing processes of the package structure 100. In some embodiments, the carrier substrate 102 is made of a material such as silicon, polymer, polymer composite, metal foil, ceramic, glass, glass epoxy, beryllium oxide, tape, or other suitable material for structural support. In some embodiments, the carrier substrate 102 is a sapphire glass substrate.

In some embodiments, the through insulating vias 104 are made of a conductive material, such as copper, titanium, tungsten, aluminum, or the like. In some embodiments, seed layers (not shown) are formed before the through insulating vias 104 are formed. The through insulating vias 104 may be formed by the following processes. A photoresist layer may be formed over the carrier substrate 102 by spin coating or the like. The photoresist layer may then be exposed to light for patterning and openings may be formed in the photoresist layer. After the openings are formed, the through insulating vias 104 may be formed in the openings by filling a conductive material in the openings by plating, such as electroplating or electroless plating, or the like. The photoresist may then be removed by an ashing or stripping process, such as using an oxygen plasma or the like.

After the through insulating vias 104 are formed, the semiconductor dies 30 and 40 (not shown in FIG. 2B, see FIG. 1B) are disposed over the carrier substrate 102, as shown in FIG. 2B in accordance with some embodiments. Although the semiconductor dies 40 are not shown in FIG. 2B, the structures of the semiconductor dies 40 may be similar to, or the same as, those of the semiconductor dies 30 shown in FIGS. 2B to 2M and described afterwards. In some embodiments, the through insulating vias 104 are sandwiched between the semiconductor dies 30 and 40 and spaced apart from the semiconductor dies 30 and 40. In some embodiments, some of the semiconductor dies 30 and 40 are formed next to each other without the through insulating vias 104 formed therebetween. In some embodiments, the closest distance between two neighboring semiconductor dies 30 and 40 is in a range from about 50 μm to about 150 μm.

In some embodiments, each of the semiconductor dies 30 and 40 includes a substrate 202, a conductive via 204 formed through the substrate 202, and an interconnect structure 206 formed over the substrate 202. In some embodiments, the interconnect structure 206 includes multiple metallization layers, and the metallization layers includes dielectric layers 208 and conductive structures 210 formed in the dielectric layers 208. The conductive structures 210 may include metal lines and metal vias formed in the dielectric layers 208. In addition, the conductive vias 204 are electrically connected to the conductive structures 210 in the interconnect structure 206 in accordance with some embodiments. In some embodiments, conductive connectors 212 are formed over the interconnect structure 206 and are electrically connected to the conductive structures 210 in the interconnect structure 206. The layout of the conductive structures 210 in the interconnect structures 208 in each of the semiconductor dies 30 and 40 may be the same or different.

The substrate 202 may be a semiconductor substrate, such as silicon, which may be doped or undoped, and which may be a silicon wafer or an active layer of a semiconductor-on-insulator (SOI) substrate, or the like. The substrate 202 may include other semiconductor materials, such as germanium, silicon carbide, gallium arsenic, gallium phosphide, indium phosphide, indium arsenide, indium antimonide, SiGe, GaAsP, AlInAs, AlGaAs, GaInAs, GaInP, GaInAsP, or combinations thereof. Other substrates, such as multi-layered or gradient substrates, may also be used. In some embodiments, the conductive via 204 is formed through the substrate 202 to electrically connect two sides of the substrate 202. In some embodiments, the conductive via 204 is made of W, Ru, Co, Cu, Ti, TiN, Ta, TaN, Mo, Ni, other applicable conductive materials, or a combination thereof.

The interconnect structure 206 may be formed by damascene processes, such as a single damascene process, a dual damascene process, or the like. In some embodiments, the dielectric layers 208 include multiple layers made of low k dielectric materials having a k value lower than 7. In some embodiments, the dielectric layers 208 are made of SiO₂, SiN, SiCN, SiOC, SiOCN, or the like. The dielectric layer 208 may be formed by chemical vapor deposition (CVD), physical vapor deposition, (PVD), atomic layer deposition (ALD), or other applicable processes. In some embodiments, the conductive structures 210 are made of W, Ru, Co, Cu, Ti, TiN, Ta, TaN, Mo, Ni, other applicable conductive materials, or a combination thereof. The conductive structures 210 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

The conductive connectors 212 may include bonding pads, microbumps, copper pillars, copper layers, nickel layers, lead free layers, electroless nickel electroless palladium immersion gold (ENEPIG) layers, Sn/Ag layers, Sn/Pb layers, or the like. In some embodiments, the conductive connectors 212 are electrically connected to the conductive structure 210 in the interconnect structure 206.

After the semiconductor dies 30 and 40 are disposed over the carrier substrate 102, an encapsulant 106 is formed over the carrier substrate 102, as shown in FIG. 2C in accordance with some embodiments. More specifically, the encapsulant 106 is formed to laterally encapsulate the through insulating vias 104 and the semiconductor dies 30 and 40. In some embodiments, the top surfaces of the through insulating vias 104 and the semiconductor dies 30 and 40 are covered by the encapsulant 106 at this step. In some embodiments, the encapsulant 106 include a molding compound such as a resin, polyimide, PPS, PEEK, PES, epoxy molding compound (EMC), or a combination thereof.

After the encapsulant 106 is formed, a planarization process is performed on the encapsulant 106 until the through insulating vias 104 and the conductive connectors 212 are exposed, as shown in FIG. 2D in accordance with some embodiments. The planarization process may be performed to remove excess portions of encapsulant 106 by using a mechanical grinding process, a chemical mechanical polishing (CMP) process, or the like. In some embodiments, the through insulating vias 104 and/or the conductive connectors 212 are also slightly polished during the planarization process. After the planarization process, the top surfaces of the through insulating vias 104 and the conductive connectors 212 are substantially level with the top surface of the encapsulant 106 in accordance with some embodiments.

Next, a redistribution structure 108 is formed over the semiconductor dies 30 and 40, the through insulating vias 104, and the encapsulant 106, and conductive pads 114 are formed over the redistribution structure 108, as shown in FIG. 2E in accordance with some embodiments. In some embodiments, the redistribution structure 108 includes multiple insulating layers 110 and redistribution layers (RDLs) 112, and the redistribution layers 112 are electrically connected to the through insulating vias 104 and the conductive connectors 212 of the semiconductor dies 30 and 40. The redistribution layers 112 may be seen as a fan-out structure. The number of the insulating layers 110 and the number of the redistribution layers 112 shown in FIG. 2E are merely an example and are not intended to be limiting. For example, the number of the insulating layers 110 and the number of the redistribution layers 112 may be in a range from about 1 to about 15.

In some embodiments, the insulating layer 110 are made of one or more suitable dielectric materials such as an oxide (e.g., silicon oxide), a nitride (e.g., silicon nitride), a polymer material, a polyimide material, a low-k dielectric material, a molding material (e.g., an EMC or the like), another dielectric material, or a combination thereof. The insulation layers 110 may be formed by a process such as spin-coating, lamination, CVD, the like, or a combination thereof. In some embodiments, the redistribution layers 112 are made of a conductive material such as copper, titanium, tungsten, aluminum, or a combination thereof. The conductive material may be formed through a deposition process such as electroplating, electroless plating, or the like.

After the redistribution structure 108 is formed, the conductive pads 114 are formed over the redistribution structure 108, as shown in FIG. 2E in accordance with some embodiments. In some embodiments, the conductive pads 114 are physically connected to the redistribution layers 112 in the redistribution structure 108. In addition, the conductive pads 114 are electrically connected to the through insulating vias 104 and the conductive connectors 212 of the semiconductor dies 30 and 40 through the redistribution layers 112 in the redistribution structure 108 in accordance with some embodiments. In some embodiments, the conductive pads 114 are made of conductive material, such as W, Ru, Co, Cu, Ti, TiN, Ta, TaN, Mo, Ni, Al, other applicable conductive materials, or a combination thereof. In some embodiments, the conductive pads 114 and the redistribution layers 112 are made of different conductive materials.

Afterwards, the package components 10 and 20 are attached (e.g. bonded) to the redistribution structure 108, as shown in FIGS. 2F and 1B in accordance with some embodiments. More specifically, the package components 10 and 20 are bonded to the conductive pads 114 over the redistribution structure 108 through conductive connectors 116 in accordance with some embodiments. As described previously, the package components 10 and 20 may be disposed over the redistribution structure 108 with the layout shown in FIGS. 1A and 1B. In addition, the package components 10 are HBM dies and the package components 20 are SoC dies in accordance with some embodiments. Furthermore, the package components 10 and 20 include the conductive pads 118 electrically connected to the devices in the package components 10 and 20 in accordance with some embodiments. In some embodiments, the conductive pads 114 are made of conductive material, such as W, Ru, Co, Cu, Ti, TiN, Ta, TaN, Mo, Ni, Al, other applicable conductive materials, or a combination thereof.

In some embodiments, the conductive connectors 116 are bonded to the conductive pads 118 of the package components 10 and 20. In some embodiments, the conductive connectors 116 are solder balls, metal pillars, controlled collapse chip connection (C4) bumps, micro bumps, electroless nickel-electroless palladium-immersion gold technique (ENEPIG) formed bumps, or the like. In some embodiments, the conductive connectors 116 are micro bumps vertically sandwiched between the conductive pads 114 and 118. In some embodiments, the conductive connectors 116 are made of a conductive material such as solder, copper, aluminum, gold, nickel, silver, palladium, tin, the like, or a combination thereof. In some embodiments, the conductive connectors 116 are formed by initially forming a layer of solder through evaporation, electroplating, printing, solder transfer, ball placement, or the like, and a reflow process may be performed in order to shape the material into the desired bump shapes. In some embodiments, the conductive connectors 116 include metal pillars (such as a copper pillar) formed by sputtering, printing, electro plating, electroless plating, CVD, or the like. The metal pillars may be solder free and have substantially vertical sidewalls. In some other embodiments, the package components 10 and 20 are bonded to the redistribution structure 108 by dielectric-to-dielectric bonding and metal-to-metal bonding.

After the package components 10 and 20 are bonded to the redistribution structure 108, an underfill 120 is formed around the package components 10 and 20, as shown in FIG. 2G in accordance with some embodiments. FIG. 2G-1 illustrates an enlarged cross-sectional view of the package structure 100 of a region R_2G shown in FIG. 2G in accordance with some embodiments. More specifically, bottom surfaces and lower portions of the sidewalls of the package components 10 and 20 are surrounded and covered by the underfill 120 in accordance with some embodiments. In addition, the conductive pads 114 and 118 and the conductive connectors 116 are embedded in the underfill 120 in accordance with some embodiments. In some embodiments, the top surfaces and the upper portions of the sidewalls of the package components 10 and 20 are not covered by the underfill 120.

More specifically, the package component 10 has a sidewall surface 10_S facing a sidewall surface 20_S of the package component 20, and the lower portions of the sidewall surfaces 10_S and 20_S are covered by the underfill 120, as shown in FIG. 2G-1 in accordance with some embodiments. In some embodiments, the package component 10 and the package component 20 are spaced apart by a space SP in X direction, and the lower region of the space SP is filled with the underfill 120. In some embodiments, the height H1 of the underfill 120 in the space SP is in a range from about 50 μm to about 100 μm. In some embodiments, the underfill 120 has a concave top surface in the space SP between the package components 10 and 20. Although not shown in FIG. 2G, the underfill 120 is formed around the lower portions of all the package components 10 and 20 shown in FIG. 1A in accordance with some embodiments. That is, the space between two neighboring package components 10 in Y direction may also have the underfill 120 similar to that shown in FIG. 2G-1.

In some embodiments, the underfill 120 is made of a polymer, epoxy, or the like. The underfill 120 may be formed by a capillary flow process after the package components 10 and 20 are attached to the redistribution structure 108. After the underfill 120 is formed, a curing process may be performed. The curing process may include heating the underfill 120 to a predetermined temperature for a predetermined period of time, using an anneal process or other heating process. The curing process may also include an ultra-violet (UV) light exposure process, an infrared (IR) energy exposure process, combinations thereof, or a combination thereof with a heating process.

Next, the molding layer 25 is formed over the underfill 120, as shown in FIG. 2H in accordance with some embodiments. More specifically, the package components 10 and 20 and the underfill 120 are covered and surrounded by the molding layer 25 in accordance with some embodiments. As described previously, the molding layer 25 includes the base material 26 and the fillers 28 embedded in the base material 26. The fillers 28 may have high thermal conductivity, so that heat generated by the package components 10 and 20 may be spread laterally through the molding layer 25. In some embodiments, the molding layer 25 is formed by mixing the fillers 28 into the base material 26. In some embodiments, the base material 26 is epoxy. In some embodiments, the fillers 28 are carbon-made particles, such as graphite, graphene, diamond-like carbon particles. In some embodiments, the molding layer 25 and the underfill 120 are made of different materials. In some embodiments, the thermal conductivity of the molding layer 25 is greater than the thermal conductivity of the underfill 120.

In some embodiments, the fillers 28 are graphite particles. In some embodiments, the particle size of the graphite particles is in a range from about 30 μm to about 70 μm. If the particle sizes are too small, the formation of the particles may be challenging. On the other hand, if the particle sizes are too large, it might be difficult to mix the particles into the base material 26 evenly. In some embodiments, the concentration of the graphite particles is in a range from about 20 wt % to about 80 wt %. If the concentration is too small, the resulting molding layer may not be able to provide sufficient thermal conductivity. On the other hand, if the concentration is too large, it might be difficult to mix the particles into the base material 26 evenly. In some embodiments, the graphite particles have the thermal conductivity in a range from about 1000 W/mK to about 4000 W/mK. In some embodiments, the graphite particles have the melting point around 3527° C. In some embodiments, the graphite particles have the density in a range from about 1.9 g/cm\hat{ }3 to about 2.2 g/cm\hat{ }3.

In some embodiments, the fillers 28 are diamond-like carbon particles. In some embodiments, the particle size of the diamond-like carbon particles is in a range from about 10 μm to about 70 μm. If the particle sizes are too small, the formation of the particles may be challenging. On the other hand, if the particle sizes are too large, it might be difficult to mix the particles into the base material 26 evenly. In some embodiments, the concentration of the diamond-like carbon particles is in a range from about 20 wt % to about 80 wt %. If the concentration is too small, the resulting molding layer may not be able to provide sufficient thermal conductivity. On the other hand, if the concentration is too large, it might be difficult to mix the particles into the base material 26 evenly. In some embodiments, the diamond-like carbon particles have the thermal conductivity in a range from about 400 W/mK to about 1000 W/mK. In some embodiments, the graphite particles have the density in a range from about 3.2 g/cm\hat{ }3 to about 3.4 g/cm\hat{ }3.

The molding layer 25 may be applied using a wafer level molding process. The molding layer 25 may be molded using, for example, compressive molding, transfer molding, molded underfill (MUF), or other methods. A curing process may be performed to the molding layer 25. The curing process may include heating the molding layer 25 to a predetermined temperature for a predetermined period of time, using an anneal process or other heating process. The curing process may also include an ultra-violet (UV) light exposure process, an infrared (IR) energy exposure process, combinations thereof, or a combination thereof with a heating process.

After the molding layer 25 is formed, a planarization process is performed until the top surfaces of the package components 10 and 20 are exposed, as shown in FIG. 2I in accordance with some embodiments. FIG. 2I-1 illustrates an enlarged cross-sectional view of the package structure 100 of a region R_2I shown in FIG. 2I in accordance with some embodiments. The planarization process may be performed to remove excess portions of molding layer 25 by using a mechanical grinding process, a chemical mechanical polishing (CMP) process, or the like. In some embodiments, the package components 10 and 20 are also slightly polished during the planarization process. After the planarization process, the top surfaces of the package components 10 and 20 are substantially level with the top surface of the molding layer 25 in accordance with some embodiments.

In some embodiments, the upper portions of the sidewall surface 10_S of the package component 10 and the sidewall surface 20_S of the package component 20 are covered by the molding layer 25, as shown in FIG. 2I-1. In some embodiments, the upper region of the space SP between the package components 10 and 20 is filled with the molding layer 25, while the lower region of the space SP is filled with the underfill 120.

In some embodiments, the contact height between the sidewall surface 10_S of the package component 10 and the molding layer 25 is greater than the contact height between the sidewall surface 10_S of the package component 10 and the underfill 120. Similarly, the contact height between the sidewall surface 20_S of the package component 20 and the molding layer 25 is greater than the contact height between the sidewall surface 20_S of the package component 20 and the underfill 120. Since the molding layer 25 has a greater thermal conductivity than the underfill 120 and the contact heights between the molding layer 25 and the package components 10 and 20 are relatively large, the heat generated by the package components 10 and 20 may be spread laterally more rapidly.

In some embodiments, the height H2 of the molding layer 25 in the space SP is greater than the height H1 of the underfill 120 in the space SP in Z direction. In some embodiments, the height H2 of the molding layer 25 in the space SP is in a range from about 600 μm to about 650 μm. In some embodiments, the molding layer 25 and the underfill 120 have a curved interface. That is, the molding layer 25 has a convex bottom surface in contact with the top surface of the underfill 120 in the space SP between the package components 10 and 20 in accordance with some embodiments. In some embodiments, the package component 10 vertically overlaps the molding layer 25 and the underfill 120 in the space SP.

Next, a carrier substrate 124 is attached to the molding layer 25 and the package components 10 and 20, as shown in FIG. 2J in accordance with some embodiments. The carrier substrate 124 may be configured to provide structural support during the manufacturing processes of the package structure 100. In some embodiments, the carrier substrate 124 is made of a material such as silicon, polymer, polymer composite, metal foil, ceramic, glass, glass epoxy, beryllium oxide, tape, or other suitable material for structural support. In some embodiments, the carrier substrate 124 is a sapphire glass substrate. In some embodiments, the carrier substrate 102 and 124 are made of the same material but with different thicknesses.

After the carrier substrate 124 is attached to the molding layer 25, the package structure is flipped upside down, and the carrier substrate 102 is removed, as shown in FIG. 2K in accordance with some embodiments. In some embodiments the carrier substrate 102 is removed by a carrier de-bonding process. The carrier de-bonding process may remove the carrier substrate 102 using any suitable process, such as etching, grinding, and mechanical peel off. In some embodiments, residues, such as adhesive, may remain on the exposed surfaces of the semiconductor dies 30 and 40 after the carrier substrate 102 is removed. Next, a cleaning process 126 is performed to clean the exposed surfaces of the semiconductor dies 30 and 40, as shown in FIG. 2L in accordance with some embodiments.

Afterwards, a redistribution structure 140 is formed over the encapsulant 106, as shown in FIG. 2M in accordance with some embodiments. In some embodiments, the redistribution structure 140 includes multiple insulating layers 142 and redistribution layers (RDLs) 144, and the redistribution layers 144 are electrically connected to the through insulating vias 104 and the conductive connectors 212 of the semiconductor dies 30 and 40. The redistribution layers 144 may be seen as a fan-out structure. The number of the insulating layers 142 and the number of the redistribution layers 144 shown in FIG. 2M are merely an example and are not intended to be limiting. For example, the number of the insulating layers 142 and the number of the redistribution layers 144 may be in a range from about 1 to about 15.

In some embodiments, the insulating layer 142 are made of one or more suitable dielectric materials such as an oxide (e.g., silicon oxide), a nitride (e.g., silicon nitride), a polymer material, a polyimide material, a low-k dielectric material, a molding material (e.g., an EMC or the like), another dielectric material, or a combination thereof. The insulation layers 142 may be formed by a process such as spin-coating, lamination, CVD, the like, or a combination thereof. In some embodiments, the redistribution layers 144 are made of a conductive material such as copper, titanium, tungsten, aluminum, another metal, or a combination thereof. The conductive material may be formed through a deposition process such as electroplating, electroless plating, or the like.

After the redistribution structure 140 is formed, conductive connectors 146 are formed over the redistribution structure 140, and the package structure 100 is formed, as show in FIG. 2M in accordance with some embodiments. The conductive connectors 146 may include bonding pads, microbumps, copper pillars, copper layers, nickel layers, lead free layers, electroless nickel electroless palladium immersion gold (ENEPIG) layers, Sn/Ag layers, Sn/Pb layers, or the like. In some embodiments, the conductive connectors 146 include conductive pillars 148 and solder balls 150 formed over the conductive pillars 148. In some embodiments, the conductive connectors 146 are electrically connected to the redistribution layers 144 in the redistribution structure 140.

As described previously, the package structure 100 includes the redistribution structure 108 and the package components 10 and 20 attached to the redistribution structure 108 in Z direction and spaced apart from each other in both X direction and Y direction, as shown in FIGS. 1A and 2M in accordance with some embodiments. In addition, the underfill 120 is formed around the lower portions of the package components 10 and 20 over the redistribution structure108, and the molding layer 25 is formed over the underfill 120 and around upper portions of the package components 10 and 20 in accordance with some embodiments.

As described previously, the package components 10 and 20 may generate heat during the operation. For example, the package components 10 may be HBM dies and the area around the HBM dies may be seen as the hot spots of the package structure 100. Therefore, the molding layer 25 with a relatively high thermal conductivity is applied to the package structure 100 to help heat dissipation during the operation in accordance with some embodiments. As shown in FIG. 2I-1, the molding layer 25 has a first portion sandwiched between the upper portions of the package components 10 and 20 in X direction, the underfill 120 has a second portion sandwiched between the lower portions of the package components 10 and 20 in X direction, and a thickness of the first portion of the molding layer 25 is greater than a thickness of the second portion of the underfill 120 in Z direction in accordance with some embodiments. The thickness of the molding layer 25 is greater than the thickness of the underfill 120, so that the heat dissipation of the device may be greatly improved. In some embodiments, the molding layer 25 is vertically sandwiched (e.g. in Z direction) between the redistribution structures 108 and 140.

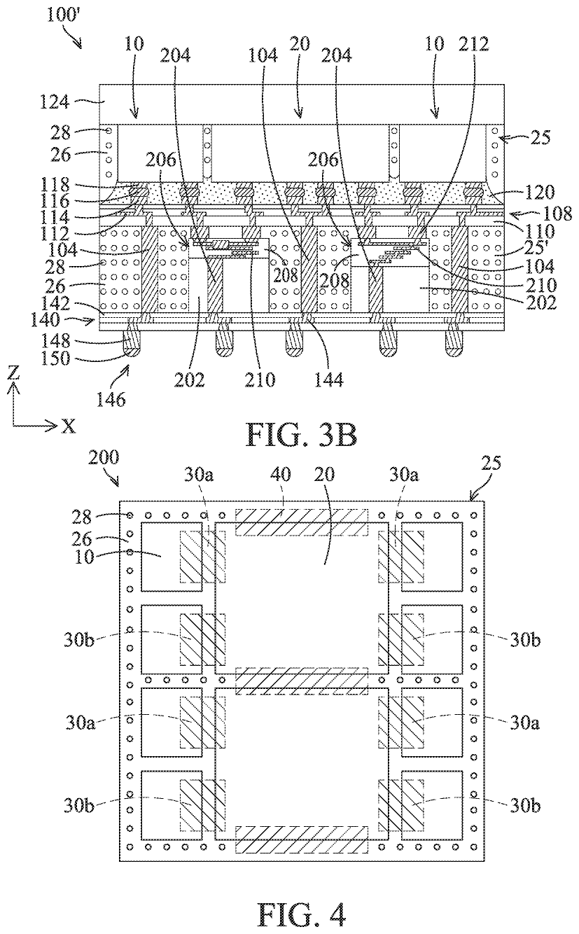

FIGS. 3A and 3B illustrate cross-sectional views of intermediate stages of manufacturing a package structure 100′ in accordance with some embodiments. The package structure 100′ may be similar to the package structure 100 described previously, except the encapsulant 106 is replaced by a molding layer 25′ in accordance with some embodiments. Processes and materials for forming the package structure 100′ may be similar to, or the same as, those for forming the package structure 100 described previously and are not repeated herein.

More specifically, the processes shown in FIGS. 2A and 2B are performed, and the molding layer 25′ is formed around the semiconductor dies 30 and 40 and the through insulating vias 104, as shown in FIG. 3A in accordance with some embodiments. That is, the semiconductor dies 30 and 40 and the through insulating vias 104 are encapsulated in the molding layer 25′ in accordance with some embodiments. Similar to the molding layer 25, the molding layer 25′ also includes the base material 26 and the fillers 28 embedded in the base material 26 in accordance with some embodiments. Since the fillers 28 have relatively high thermal conductivity, the heat may be spread laterally more rapidly.

In some embodiments, the fillers 28 in the molding layer 25′ and the fillers 28 in the molding layer 25 are the same. In some embodiments, the fillers 28 in the molding layer 25′ and the fillers 28 in the molding layer 25 are the same but with different concentrations. In some embodiments, the fillers 28 in the molding layer 25′ and the fillers 28 in the molding layer 25 are the same but with different particle sizes. In some embodiments, the fillers 28 in the molding layer 25′ and the fillers 28 in the molding layer 25 are different but the base materials 26 are the same.

Afterwards, the processes shown in FIGS. 2D to 2M are performed to form the package structure 100′, as shown in FIG. 3B in accordance with some embodiments. The package structure 100′ may also have the layout shown in FIGS. 1A and 1B. Similar to the package structure 100, the package structure 100′ includes the redistribution structure 108, the package components 10 and 20 attached to a first side of the redistribution structure 108 and spaced apart from each other in both X and Y directions, and the semiconductor dies 30 and 40 attached to a second side of the redistribution structure 108 in accordance with some embodiments.

Furthermore, the molding layer 25 is formed over the first side of the redistribution structure 108, and the molding layer 25′ is formed over the second side of the redistribution structure 108 in accordance with some embodiments. In some embodiments, the molding layer 25′ is vertically sandwiched between (e.g. in Z direction) the redistribution structure 104 and the carrier substrate 124. In some embodiments, the molding layers 25 and 25′ includes the same base material but include different kinds of carbon-made particles.

FIG. 4 illustrates a diagrammatic top view of a package structure 200 in accordance with some embodiments. The package structure 200 may be similar to the package structures 100 and 100′ described previously, except the size of semiconductor dies are different with those in the package structures 100 and 100′ in accordance with some embodiments. Processes and materials for forming the package structure 200 may be similar to, or the same as, those for forming the package structures 100 and 100′ described previously and are not repeated herein.

As shown in FIG. 4, the package structure 200 includes the package components 10 and 20 and the semiconductor dies 40, but the semiconductor dies 30 are replaced by semiconductor dies 30a and 30b in accordance with some embodiments. More specifically, each of the semiconductor dies 30a and 30b are configured to connect the electrical signals between one of the package components 10 and one of the package component 20 in accordance with some embodiments. The function and formation of the semiconductor dies 30a and 30b may be the same as those of the semiconductor dies 30 and therefore are not repeated herein.

Similar to the package structure 100, in the package structure 200, the package components 10 and 20 are encapsulated (e.g. surrounded) by the molding layer 25 in accordance with some embodiments. In some embodiments, the semiconductor dies 30a, 30b, and 40 are encapsulated (e.g. surrounded) by the molding layer 25′, similar to the package 100′ shown in FIG. 3B. Accordingly, the heat generated by the package components 10 and 20 and the semiconductor dies 30a, 30b, and 40 during the operation can be dissipated by the molding layers 25 and 25′, and the temperature of the device may be reduced. The cross-sectional views of the package structure 200 may be the same as those of the package structures 100 and 100′ shown in FIGS. 2M and 3 B and therefore the details of the structure are not repeated herein.

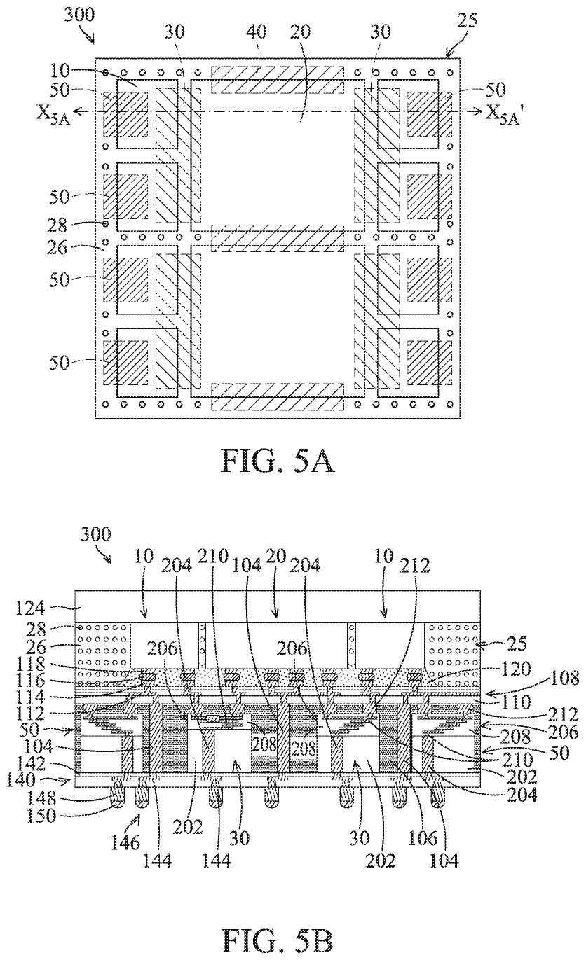

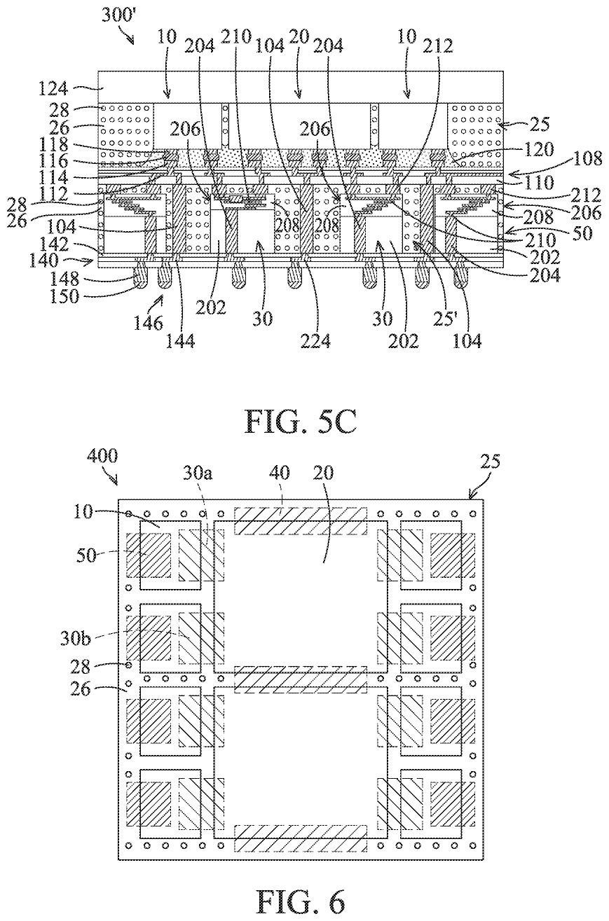

FIG. 5A illustrates a diagrammatic top view of a package structure 300 in accordance with some embodiments. FIG. 5B illustrates a cross-sectional view of the package structure 300 shown along line X_{5A}-X_{5A}′ in FIG. 5A in accordance with some embodiments. The package structure 300 may be similar to the package structure 100 described previously, except semiconductor dies 50 are disposed along with the semiconductor dies 30 and 40 in accordance with some embodiments. Processes and materials for forming the package structure 300 may be similar to, or the same as, those for forming the package structure 100 described previously and are not repeated herein.

As shown in FIG. 5A, the package structure 300 includes the package components 10 and 20 and the semiconductor dies 30 and 40, and additional semiconductor dies 50 are also disposed (e.g. bonded) to the redistribution structure 108 in accordance with some embodiments. The semiconductor dies 50 may be configured to control the power of the package components 10. More specifically, the semiconductor dies 30, 40, and 50 are disposed over the carrier substrate 102, and the processes shown in FIGS. 2C to 2M are performed to form the package structure 300, as shown in FIG. 5B in accordance with some embodiments. In some embodiments, each of the semiconductor dies 50 partially overlaps one of the package components 10. Similar to the package structure 100, the package components 10 and 20 are encapsulated (e.g. surrounded) by the molding layer 25, so that heat generated by the package components 10 and 20 may be dissipated more rapidly in accordance with some embodiments.

FIG. 5C illustrates a cross-sectional view of a package structure 300′ in accordance with some embodiments. The package structure 300′ may be similar to the package structure 300 described previously, except the encapsulant 106 is replaced by the molding layer 25′ in accordance with some embodiments. Processes and materials for forming the package structure 300′ may be similar to, or the same as, those for forming the package structure 300 described previously and are not repeated herein.

Similar to the package structure 300, the package components 10 and 20 are encapsulated (e.g. surrounded) by the molding layer 25 in accordance with some embodiments. In some embodiments, the semiconductor dies 30, 40, and 50 are encapsulated (e.g. surrounded) by the molding layer 25′, similar to the package 100′ shown in FIG. 3B. Accordingly, the heat generated by the package components 10 and 20 during the operation can be dissipated by the molding layer 25, and the heat generated by the semiconductor dies 30, 40, and 50 during the operation can be dissipated by the molding layer 25′, and the temperature of the device may be reduced. The layout of the package structure 300′ may be the same as those of the package structure 300 shown in FIG. 5A and therefore the details of the layout are not repeated herein.

FIG. 6 illustrates a diagrammatic top view of a package structure 400 in accordance with some embodiments. The package structure 400 may be similar to the package structure 200 described previously, except the semiconductor dies 50 are also disposed in accordance with some embodiments. Processes and materials for forming the package structure 400 may be similar to, or the same as, those for forming the package structures 100, 200, and 300 described previously and are not repeated herein.

As shown in FIG. 6, the package structure 400 includes the package components 10 and 20 and the semiconductor dies 30a, 30b, 40, and 50 in accordance with some embodiments. Similar to the package structure 100, in the package structure 400, the package components 10 and 20 are encapsulated (e.g. surrounded) by the molding layer 25 in accordance with some embodiments. In some embodiments, the semiconductor dies 30a, 30b, 40, and 50 are encapsulated (e.g. surrounded) by the molding layer 25′. Accordingly, the heat generated by the package components 10 and 20 and the semiconductor dies 30a, 30b, 40, and 50 during the operation can be dissipated by the molding layers 25 and 25′, and the temperature of the device may be reduced. The cross-sectional views of the package structure 400 may be the same as those of the package structures 300 and 300′ shown in FIGS. 5B and 5C and therefore the details of the structure are not repeated herein.

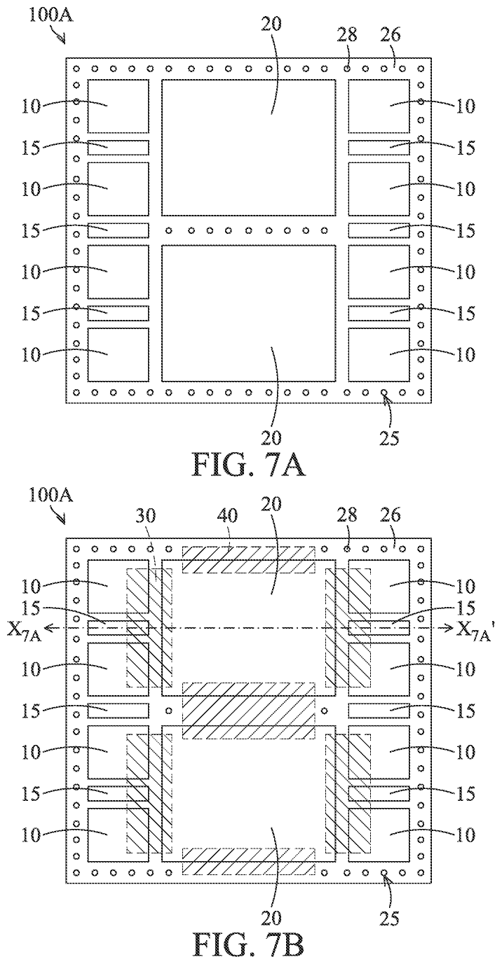

FIGS. 7A and 7B illustrate diagrammatic top views of a package structure 100A in accordance with some embodiments. The package structure 100A may be similar to the package structure 100 described previously, except dummy dies 15 are also attached to the redistribution structure 108 in accordance with some embodiments. Processes and materials for forming the package structure 100A may be similar to, or the same as, those for forming the package structure 100 described previously and are not repeated herein.

More specifically, FIG. 7A illustrates the layout of the package components 10 and 20 and the dummy dies 15 in the package structure 100A in accordance with some embodiments. As described previously, the package components 10 may be HBM dies and may be the hot spots of the device during the operation. Therefore, dummy dies 15 may be applied to the package structure 100A to further help the dissipation of heat. In addition, the package components 10 and 20 and the dummy dies 15 are also encapsulated (e.g. surrounded) by the molding layer 25 in accordance with some embodiments. Bother the dummy dies 15 and the molding layer 25 may help the dissipation of heat.

In some embodiments, the spaces between the package components 10 and 20 and the dummy dies 15 in both X direction and Y direction are filled with the molding layer 25. In addition, since the dummy dies 25 are used for heat dissipation, the dummy dies 25 are free of active and/or passive devices in accordance with some embodiments. In some embodiments, the dummy dies 15 are spaced apart from the package components 10 in Y direction. In some embodiments, the dummy die 15 is sandwiched between two package components 10 in Y direction, so that the heat dissipation between the package components 10 may be further improved. In some embodiments, the sidewall surfaces of the package components 10 and the dummy dies 15 are substantially aligned with each other.

In some embodiments, the dummy dies 15 are spaced apart from the package components 20 in X direction. In some embodiments, the molding layer 25 is laterally sandwiched between the dummy die 15 and the package component 20 in X direction. In some embodiments, the molding layer 25 is laterally sandwiched between the dummy die 15 and the package component 10 in Y direction.

FIG. 7B further illustrates the layout of the semiconductor dies 30 and 40 in the package structure 100A in accordance with some embodiments. In some embodiments, each of the semiconductor dies 30 vertically overlaps two package components 10, one package component 20, and one dummy die 15. That is, the projection area of each of the semiconductor dies 30 overlaps two package components 10, one package component 20, and one dummy die 15 in the top view in accordance with some embodiments. In some embodiments, the package components 10 and the dummy dies 15 are substantially aligned in Y direction. In some embodiments, the sidewalls of the package components 10 and the dummy dies 15 are substantially aligned in Y direction. In some embodiments, the width of the package component 10 is substantially equal to the width of the dummy die 15 in X direction. In some embodiments, the width of the package component 10 is greater than the width of the dummy die 15 in Y direction. In some embodiments, the width of the package component 20 is greater than the width of the dummy die 15 in both X direction and Y direction.

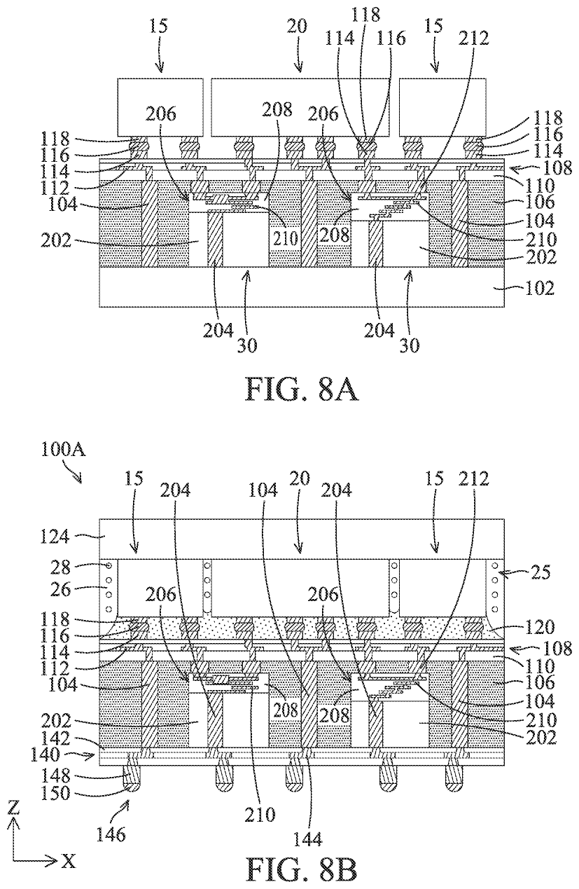

FIGS. 8A and 8B illustrate cross-sectional views of intermediate stages of manufacturing the package structure 100A in accordance with some embodiments. More specifically, the cross-sectional views are shown along line X_{7B}-X_{7B}′ in FIG. 7B in accordance with some embodiments. More specifically, the processes shown in FIGS. 2A to 2E are performed, and the package components 10 and 20 and the dummy dies 15 are bonded to the redistribution structure 108, as shown in FIG. 8A in accordance with some embodiments. Similar to the package components 10 and 20, the dummy dies 15 are bonded to the redistribution structure 108 through bonding the conductive pads 114 and 118 through the conductive connectors 116 in accordance with some embodiments. In some embodiments, the dummy dies 15 are bonded to the redistribution structure 108 after the package components 10 and 20 are bonded. In some other embodiments, the dummy dies 15 are bonded to the redistribution structure 108 by an adhesion layer. In some other embodiments, the dummy dies 15 are bonded to the redistribution structure 108 by dielectric-to-dielectric and metal-to-metal bonding. In some embodiments, the dummy dies 15 and the semiconductor dies 30 and 40 are at opposite sides of the redistribution structure 108.

As described above, instead of being used as electrical devices, the dummy dies 15 may help the dissipation of heat generated from the package components 10. Therefore, the dummy dies 25 are free of active and/or passive devices in accordance with some embodiments. In addition, the dummy dies 25 are electrically isolated from the package components 10 and 20, the redistribution layers 112 in the redistribution structure 108, the through insulating vias 104, and the semiconductor dies 30 and 40 in accordance with some embodiments. In some embodiments, the dummy dies 15 include one or more materials having a relatively high thermal conductivity. In some embodiments, the dummy dies 15 are made of a material such as silicon (e.g., bulk silicon), silicon oxide, silicon carbine, aluminum nitride, a ceramic material, the like, or a combination thereof.

After the package components 10 and 20 and the dummy dies 15 are bonded to the redistribution structure 108, the processes shown in FIGS. 2G to 2M are performed to form the package structure 100A, as shown in FIG. 8B in accordance with some embodiments. Similar to the package components 10, the underfill 120 is formed around the lower portions of the dummy dies 15 over the redistribution structure108, and the molding layer 25 is formed over the underfill 120 and around upper portions of the dummy dies 15 in accordance with some embodiments.

In some embodiments, the underfill 120 is in direct contact with the bottom surfaces and the lower portions of the sidewall surfaces of the dummy dies 15, and the molding layer 25 is in contact with the upper portions of the sidewall surfaces of the dummy dies 15. Since the dummy dies 15 may also help the dissipation of heat, the heat generated by the package components 10 during the operation can be dissipated by both the molding layer 25 and the dummy dies 15, and the temperature of the resulting device may be reduced. The cross-sectional view at the package component 10 is the same as that shown in FIG. 2M and is not repeated herein.

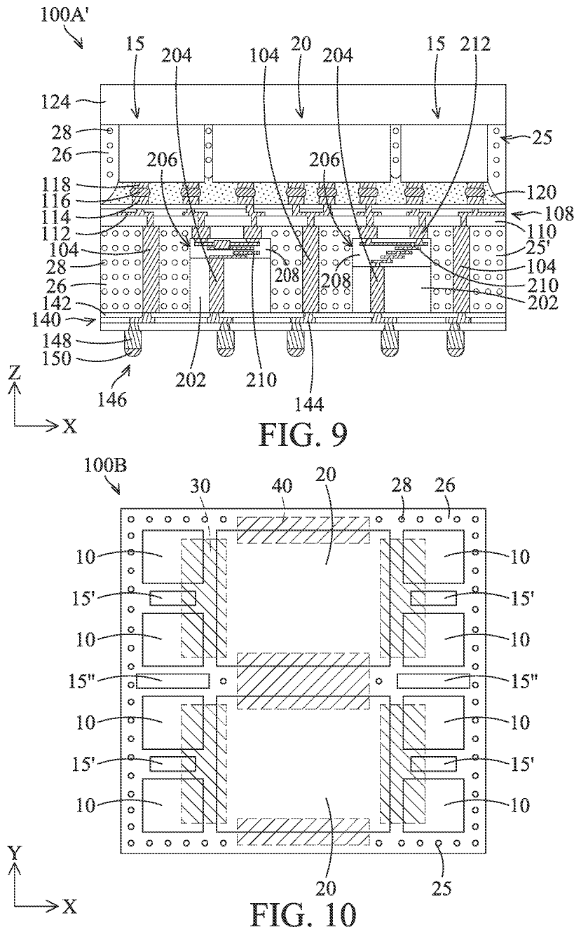

FIG. 9 illustrates a cross-sectional view of a package structure 100A′ in accordance with some embodiments. The package structure 100A′ may be similar to the package structure 100A described previously, except the encapsulant 106 is replaced by the molding layer 25′ in accordance with some embodiments. Processes and materials for forming the package structure 100A′ may be similar to, or the same as, those for forming the package structures 100 and 100A described previously and are not repeated herein.

Similar to the package structure 100A, the package components 10 and 20 and the dummy dies 15 are encapsulated (e.g. surrounded) by the molding layer 25 in accordance with some embodiments. In some embodiments, the semiconductor dies 30 and 40 are encapsulated (e.g. surrounded) by the molding layer 25′. Accordingly, the heat generated by the semiconductor dies 30 and 40 during the operation can be dissipated by the molding layer 25′ and the temperature of the device may be reduced. The layout of the package structure 100A′ may be the same as those of the package structure 100A shown in FIGS. 7A and 7B and therefore the details of the structure are not repeated herein. The cross-sectional view at the package component 10 is the same as that shown in FIG. 3B and is not repeated herein.

FIG. 10 illustrates a layout of a package structure 100B in accordance with some embodiments. The package structure 100B may be similar to the package structure 100A described previously, except dummy dies 15′ and 15″ have different sizes with the dummy dies 15 shown in FIGS. 7A and 7B in accordance with some embodiments. Processes and materials for forming the package structure 100B may be similar to, or the same as, those for forming the package structures 100 and 100A described previously and are not repeated herein.

More specifically, the package components 10 and 20 and the dummy dies 15′ and 15″ are encapsulated (e.g. surrounded) by the molding layer 25 in accordance with some embodiments. In some embodiments, the spaces between the package components 10 and 20 and the dummy dies 15′ and 15″ in both X direction and Y direction are filled with the molding layer 25. In some embodiments, the width of the dummy die 15′ is smaller than the width of the package component 10 in both X direction and Y direction. In some embodiments, the width of the dummy die 15′ is smaller than the width of the package component 20 in both X direction and Y direction. In some embodiments, the width of the dummy die 15″ is greater than the width of the package component 10 in X direction. In some embodiments, the width of the dummy die 15′ is different from the width of the dummy die 15″. The materials and functions of the dummy dies 15′ and 15″ may be similar to, or the same as, those of the dummy dies 15 described previously and are not repeated herein. In addition, the cross-sectional views of the package structure 100B may be the same as those shown in FIGS. 2M, 3B, 8B and 9 and therefore are not repeated herein.

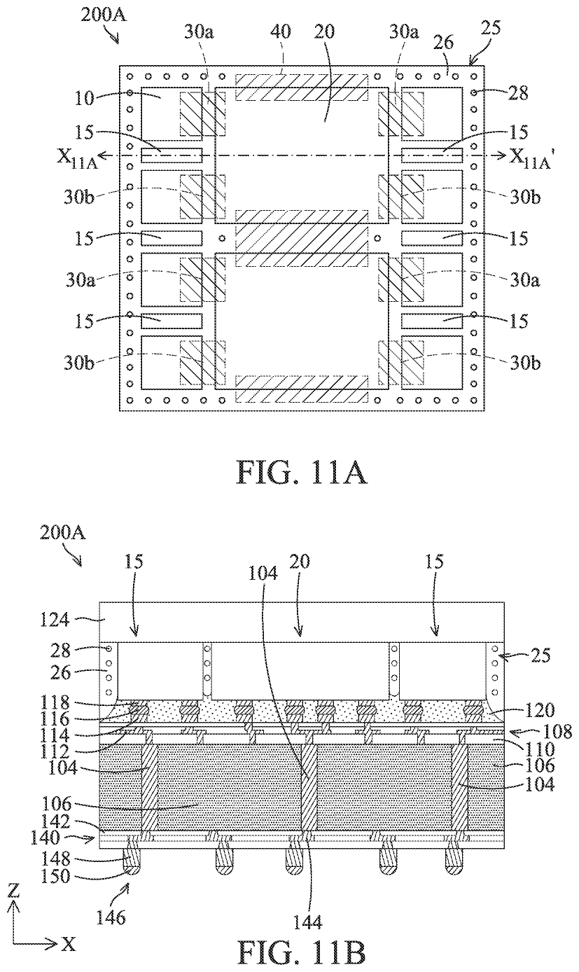

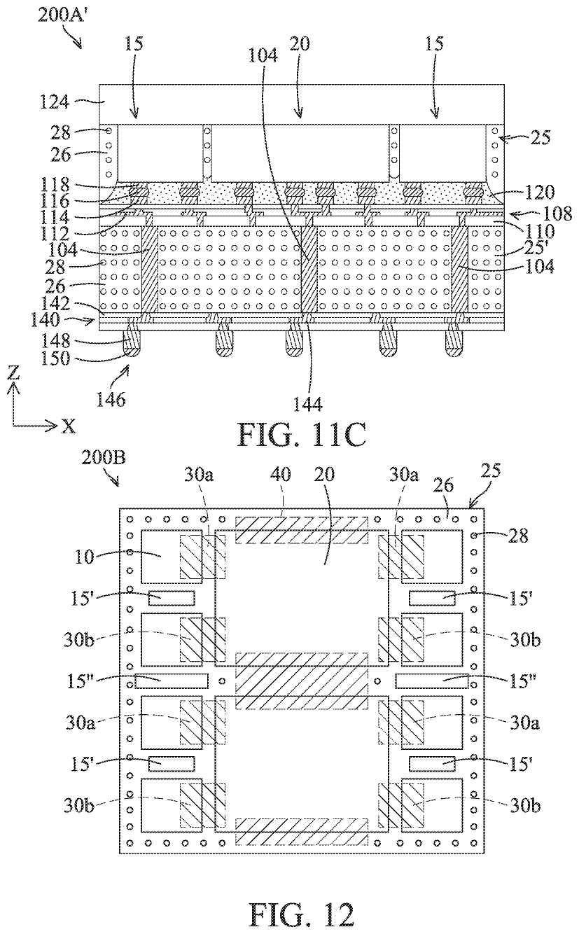

FIG. 11A illustrates a diagrammatic top view of a package structure 200A in accordance with some embodiments. FIG. 11B illustrates a cross-sectional view of the package structure 200A shown along line X_{11B}-X_{11B}′ in FIG. 11A in accordance with some embodiments. The package structure 200A may be similar to the package structure 200 described previously, except the dummy dies 15 are disposed along with the package components 10 and 20 in accordance with some embodiments. Processes and materials for forming the package structure 200A may be similar to, or the same as, those for forming the package structure 200 described previously and are not repeated herein.

Similar to the package structure 100A described previously, the package components 10 and 20 and the dummy dies 15 are encapsulated (e.g. surrounded) by the molding layer 25, as shown in FIGS. 11A and 11B in accordance with some embodiments. In some embodiments, the semiconductor dies 30a and 30b overlap the package components 10 and 20 but do not overlap the dummy dies 15 in the top view. The cross-sectional view at the package component 10 is the same as that shown in FIG. 2M and is not repeated herein.

FIG. 11C illustrates a cross-sectional view of a package structure 200A′ in accordance with some embodiments. The package structure 200A′ may be similar to the package structure 200A described previously, except the encapsulant 106 is replaced by the molding layer 25′ in accordance with some embodiments. Processes and materials for forming the package structure 200A′ may be similar to, or the same as, those for forming the package structure 200A described previously and are not repeated herein. The layout of the package structure 200A′ may be the same as those of the package structure 200A shown in FIG. 11A and therefore the details of the layout are not repeated herein. The cross-sectional view at the package component 10 is the same as that shown in FIG. 3B and is not repeated herein.

FIG. 12 illustrates a layout of a package structure 200B in accordance with some embodiments. The package structure 200B may be similar to the package structure 200A described previously, except the dummy dies 15′ and 15″ have different sizes with the dummy dies 15 shown in FIG. 11A in accordance with some embodiments. Processes and materials for forming the package structure 200B may be similar to, or the same as, those for forming the package structures 200 and 200A described previously and are not repeated herein. The cross-sectional views of the package structure 200B may be the same as those shown in FIGS. 2M, 3B, 11B and 11C and therefore are not repeated herein.

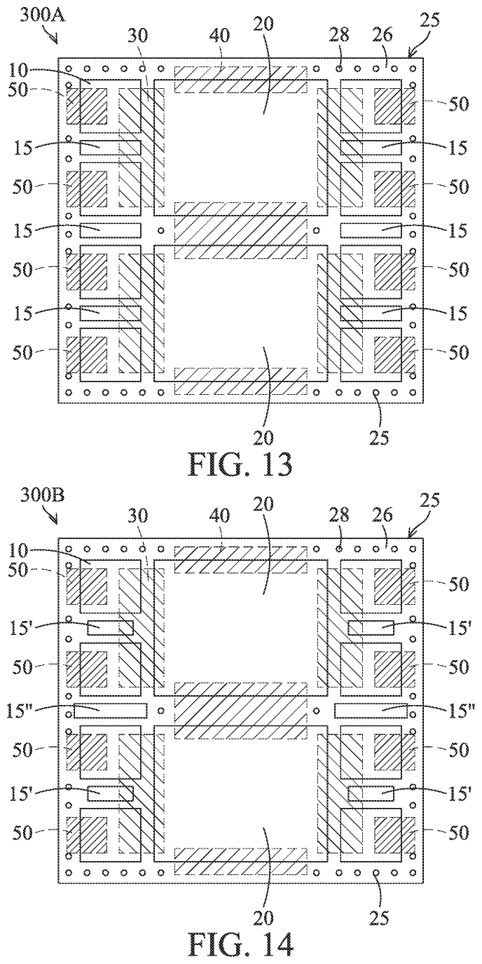

FIG. 13 illustrates a diagrammatic top view of a package structure 300A in accordance with some embodiments. The package structure 300A may be similar to the package structure 300 described previously, except the dummy dies 15 are disposed along with the package components 10 and 20 in accordance with some embodiments. Processes and materials for forming the package structure 300A may be similar to, or the same as, those for forming the package structure 300 described previously and are not repeated herein. In addition, the cross-sectional views of the package structure 300A may be the same as those shown in FIGS. 2M, 3B, 8B and 9 and therefore are not repeated herein.

FIG. 14 illustrates a layout of a package structure 300B in accordance with some embodiments. The package structure 300B may be similar to the package structure 300A described previously, except the dummy dies 15′ and 15″ have different sizes with the dummy dies 15 shown in FIG. 13 in accordance with some embodiments. Processes and materials for forming the package structure 300B may be similar to, or the same as, those for forming the package structures 300 and 300A described previously and are not repeated herein. The cross-sectional views of the package structure 300B may be the same as those shown in FIGS. 2M, 3B, 8B and 9 and therefore are not repeated herein.

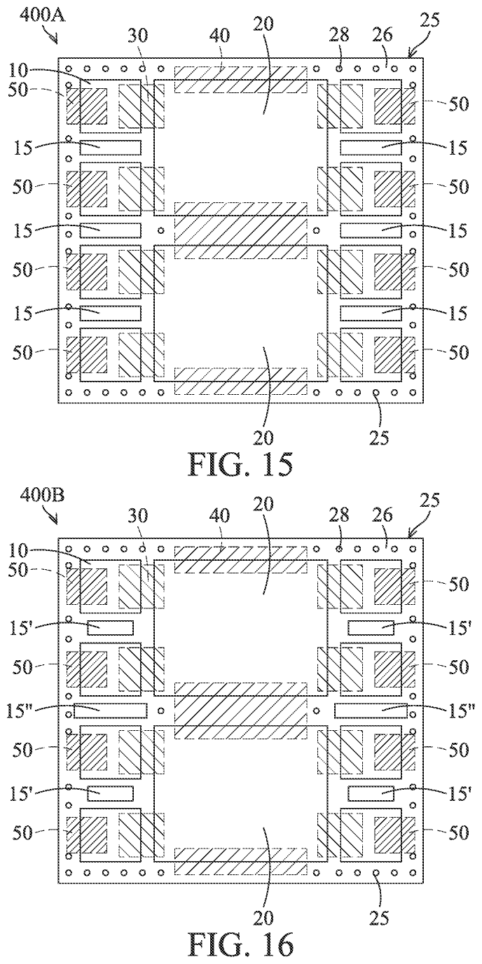

FIG. 15 illustrates a diagrammatic top view of a package structure 400A in accordance with some embodiments. The package structure 400A may be similar to the package structure 400 described previously, except the dummy dies 15 are disposed along with the package components 10 and 20 in accordance with some embodiments. Processes and materials for forming the package structure 400A may be similar to, or the same as, those for forming the package structure 400 described previously and are not repeated herein. In addition, the cross-sectional views of the package structure 400A may be the same as those shown in FIGS. 2M, 3B, 11B and 11C and therefore are not repeated herein.

FIG. 16 illustrates a layout of a package structure 400B in accordance with some embodiments. The package structure 400B may be similar to the package structure 400A described previously, except the dummy dies 15′ and 15″ have different sizes with the dummy dies 15 shown in FIG. 15 in accordance with some embodiments. Processes and materials for forming the package structure 400B may be similar to, or the same as, those for forming the package structures 400 and 400A described previously and are not repeated herein. The cross-sectional views of the package structure 400B may be the same as those shown in FIGS. 2M, 3B, 11B and 11C and therefore are not repeated herein.

As described previously, the package components 10 and 20 may generate heat during the operation. For example, the package components 10 may be HBM dies, and the area of the HBM dies may be seen as hot spots of the package structures. Accordingly, in some embodiments, the molding layer 25 with relatively high thermal conductivity is formed around the package components 10 and 20, so the dissipation of heat may be improved, and the temperature around the package components 10 may be reduced (e.g. about 12° C.) during operation. In addition, the dummy dies 15, 15′, 15″ are bonded to the redistribution structure 108 between the package components 10, so the temperature around the package components 10 may further be reduced in accordance with some embodiments. Furthermore, the molding layer 25′ is further formed around the semiconductor dies 30, 30a, 30b, 40, and 50, so the heat generated by the semiconductor dies may also be spread more rapidly. Accordingly, the temperature of the package structures, especially at the hot spots around the package components 10, may be reduced, and the performance of the package structures may therefore be improved.

It should be appreciated that the elements shown in the package structures 100, 100′, 200, 300, 300′, 400, 100A, 100A′, 100B, 200A, 200A′, 200B, 300A, 300B, 400A, and 400B may be combined and/or exchanged. In addition, it should be noted that same elements in FIGS. 1A to 16 may be designated by the same numerals and may include materials that are the same or similar and may be formed by processes that are the same or similar; therefore such redundant details are omitted in the interests of brevity. In addition, although FIGS. 1A to 16 are described in relation to the method, it will be appreciated that the structures disclosed in FIGS. 1A to 16 are not limited to the method but may stand alone as structures independent of the method. Similarly, the methods shown in FIGS. 1A to 16 are not limited to the disclosed structures but may stand alone independent of the structures.

Also, while the disclosed methods are illustrated and described above as a series of acts or events, it should be appreciated that the illustrated ordering of such acts or events may be altered in some other embodiments. For example, some acts may occur in a different order and/or concurrently with other acts or events apart from those illustrated and/or described above. In addition, not all illustrated acts may be required to implement one or more aspects or embodiments of the description above. Furthermore, one or more of the acts depicted above may be carried out as one or more separate acts and/or phases.

Embodiments of package structures may be provided. The package structure may include package components and semiconductor dies disposed at opposite sides of a redistribution structure. In addition, a molding layer with a relatively high thermal conductivity is formed around the package components. The molding layer may include fillers with high thermal conductivity. The molding layer may help the dissipation of heat generated by the package components, and therefore the temperature of the package structure during operation may be reduced.

A package structure is provided. The package structure includes a redistribution structure and a first package component and a second package component attached to the redistribution structure in a first direction and spaced apart from each other in a second direction. The package structure further includes an underfill formed around lower portions of the first package component and the second package component over the redistribution structure and a molding layer formed over the underfill and around upper portions of the first package component and the second package component. In addition, the molding layer includes a base material and fillers embedded in the base material. Furthermore, a thermal conductivity of the fillers is greater than about 400 W/mK.

A package structure is provided. The package structure includes a first redistribution structure and a first package component and a second package component attached to a first side of the first redistribution structure and spaced apart from each other in a first direction. The package structure further includes an underfill formed around the first package component and the second package component and a first molding layer formed over the underfill and over the first side of the first redistribution structure. In addition, the first molding layer includes first carbon-made particles, and a thermal conductivity of the first molding layer is greater than a thermal conductivity of the underfill. The package structure further includes a first semiconductor die attached to a second side of the first redistribution structure, and the first semiconductor die has a first projection area partially overlapping the first package component and the second package component in a top view.

A method for forming a package structure is provided. The method includes forming a redistribution structure and disposing a first package component and a second package component over the redistribution structure. In addition, the first package component is spaced apart from the second package component by a first space. The method further includes forming an underfill around the first package component and the second package component and in a lower region of the first space and forming a first molding layer covering the first package component, the second package component, and the underfill. In addition, the first molding layer includes first carbon-made particles. The method further includes partially removing the first molding layer until top surfaces of the first package component and the second package component are exposed, and an upper region of the first space is filled with the first molding layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a redistribution structure;
a first package component and a second package component attached to a first side of the redistribution structure;
an underfill over the redistribution structure around lower portions of the first package component and the second package component; and
a molding layer formed over the underfill and around upper portions of the first package component and the second package component, wherein the molding layer comprises:
a base material; and
fillers embedded in the base material, wherein a thermal conductivity of the fillers is greater than about 400 W/mK.

2. The package structure of claim 1, wherein the molding layer has a first portion between the upper portions of the first package component and the second package component, the underfill has a second portion between the lower portions of the first package component and the second package component, a thickness of the first portion of the molding layer is greater than a thickness of the second portion of the underfill.

3. The package structure of claim 1, further comprising:
a dummy die attached to the first side of the redistribution structure and spaced apart from the first package component, wherein the molding layer extends between the dummy die and the first package component.

4. The package structure of claim 3, wherein the molding layer extends between the dummy die and the second package component.

5. The package structure of claim 3, further comprising:
a third package component attached to the first side of the redistribution structure, wherein sidewall surfaces of the first package component, the dummy die, and the third package components are substantially aligned with each other.

6. The package structure of claim 1, wherein the fillers comprise graphite, graphene, or diamond-like carbon.

7. The package structure of claim 1, wherein a concentration of the fillers in the molding layer is in a range between 20 wt % and 80 wt %.

8. A package structure, comprising:
a first redistribution structure;
a first package component and a second package component attached to a first side of the first redistribution structure and spaced apart from each other;
an underfill around the first package component and the second package component;
a first molding layer over the underfill and over the first side of the first redistribution structure, wherein the first molding layer comprises first carbon-made particles, wherein a thermal conductivity of the first molding layer is greater than a thermal conductivity of the underfill; and
a first semiconductor die attached to a second side of the first redistribution structure, wherein the first semiconductor die partially overlaps the first package component and the second package component in a top view.

9. The package structure of claim 8, wherein the first carbon-made particles are graphite or diamond-like carbon.

10. The package structure of claim 8, further comprising
a second redistribution structure attached to the first semiconductor die; and
a second molding layer around the first semiconductor die, wherein the second molding layer comprises second carbon-made particles.

11. The package structure of claim 10, wherein the first carbon-made particles are different from the second carbon-made particles.

12. The package structure of claim 8, further comprising:
a dummy die attached to the first side of the first redistribution structure; and
a third package component attached to the first side of the first redistribution structure, wherein the first molding layer is in contact with the dummy die and the third package component.

13. The package structure of claim 12, wherein the first semiconductor die partially overlaps the dummy die in the top view.

14. The package structure of claim 13, wherein the first semiconductor die partially overlaps the third package component in the top view.

15. The package structure of claim 8, wherein the first package component has a first sidewall surface facing the second package component in the first direction, wherein a contact height between the first sidewall surface and the first molding layer is greater than a contact height between the first sidewall surface and the underfill.

16. A method for forming a package structure, comprising:
forming a redistribution structure;
disposing a first package component and a second package component over the redistribution structure, wherein the first package component is spaced apart from the second package component by a first space;
forming an underfill around the first package component and the second package component and in a lower region of the first space;
forming a first molding layer over the first package component, the second package component, and the underfill, wherein the first molding layer comprises first carbon-made particles; and
partially removing the first molding layer to expose top surfaces of the first package component and the second package component, wherein an upper region of the first space is filled with the first molding layer.

17. The method of claim 16, wherein the first molding layer comprises the first carbon-made particles in a base material, wherein a concentration of the fillers in the molding layer is in a range between 20 wt % and 80 wt %.

18. The method of claim 16, further comprising:
disposing a first semiconductor die over a carrier substrate; and
forming a second molding layer around the first semiconductor die, wherein the second molding layer comprises second carbon-made particles, wherein forming the redistribution structure comprises forming the redistribution structure over the first semiconductor die and the second molding layer.

19. The method of claim 18, wherein the first molding layer and the second molding layer comprise a same base material, while the first carbon-made particles are different from the second carbon-made particles.

20. The method of claim 18, wherein the first molding layer and the second molding layer are on opposite sides of the redistribution structure, and the first semiconductor die vertically overlaps both the first package component and the second package component.
